(19) United States
(12) Patent Application Publication
(10) Pub. No.: US 2020/0154557 A1
(43) Pub. Date: May 14, 2020

(54) CIRCUIT BOARD STRUCTURE

(71) Applicant: Sumitomo Wiring Systems, Ltd., Yokkaichi (JP)

(72) Inventors: Junya Aichi, Yokkaichi (JP); Jun Ikeda, Yokkaichi (JP)

(21) Appl. No.: 16/678,158

(22) Filed: Nov. 8, 2019

(30) Foreign Application Priority Data
Nov. 9, 2018 (JP) 2018-211603

(51) Int. Cl. H05K 1/02; H05K 1/18

(52) U.S. Cl. CPC H05K 1/021; H05K 1/184; H05K 1/183

(57) ABSTRACT

Provided is a circuit board structure that can enhance heat dissipation performance of heat generated by a semiconductor element and effectively perform heat dissipation. A circuit board structure includes a circuit board portion having a mounting face on which semiconductor elements are mounted, an opposing plate portion that is opposed to the mounting face and that dissipates heat from the circuit board portion, a plurality of semiconductor elements mounted on the mounting face in a row, and a recessed portion formed at a position corresponding to the plurality of semiconductor elements in the opposing plate portion.

### CROSS-REFERENCE TO RELATED APPLICATIONS

This application claims priority of Japanese Patent Application No. JP 2018-211603 filed on Nov. 9, 2018, the contents of which are incorporated herein.

### TECHNICAL FIELD

The present disclosure relates to a circuit board structure including a circuit board.

### BACKGROUND

Typically, circuit boards are known on which conductive members (also called bus bars, etc.) that form a circuit through which a comparatively large current can flow are mounted.

On the other hand, JP 2018-063982A discloses an electronic apparatus in which holes are formed in a housing so as to quickly dissipate heat generated by an electric component mounted inside the housing to the outside of the housing and to take in the outside air into the housing to cool the electronic component.

JP 2018-063982A is an example of related art.

In the above-described circuit assembly, a large current flows through electric components such as semiconductor elements, and thus a lot of heat is generated in the electric components and the conductive members. The heat generated in this manner may cause a malfunction of the electric components, and there is also a risk that the electric components and the like in the region may suffer secondary heat damage.

In order to address the above problems, the electronic apparatus disclosed in JP 2018-063982A is provided with the holes that are formed in the housing. However, due to the holes being formed in the housing, there is a risk that dusts, water and the like will enter into the housing from the outside. In order to prevent such a risk, the electronic apparatus disclosed in JP 2018-063982A is separately provided with a filter, and as a result, there are problems in that the structure is complicated and manufacturing costs are increased.

The present disclosure has been made in view of these circumstances, and an object of the present disclosure is to provide a circuit board structure that can enhance heat dissipation performance of heat generated by a semiconductor element and efficiently perform heat dissipation.

### SUMMARY

The circuit board structure according to an aspect of the present disclosure includes a circuit board portion having a mounting face on which semiconductor elements are mounted, an opposing plate portion that is opposed to the mounting face and that dissipates heat from the circuit board portion, a plurality of semiconductor elements mounted on the mounting face in a row, and a recessed portion formed at a position corresponding to the plurality of semiconductor elements in the opposing plate portion.

### Advantageous Effects of Disclosure

According to the aspect of the present disclosure, it is possible to enhance heat dissipation performance of heat generated by the semiconductor elements, and efficiently perform heat dissipation.

### BRIEF DESCRIPTION OF THE DRAWINGS

FIG. 1 is a perspective view of an electric apparatus according to an embodiment;

FIG. 2 is an exploded view of the electric apparatus according to the embodiment;

FIG. 3 is a schematic bottom view of a circuit board housing portion of the electric apparatus according to the embodiment;

FIG. 4 is a schematic front view of the electric apparatus according to the embodiment;

FIG. 5 is a schematic side view of the electric apparatus according to the embodiment;

FIG. 6 is a schematic bottom view of the electric apparatus according to the embodiment;

FIG. 7 is a vertical cross-sectional view taken along line VII-VII in FIG. 6, and

FIG. 8 is a partial vertical cross-sectional view showing a relationship between a recessed portion and a FET in the electric apparatus according to the embodiment.

### DETAILED DESCRIPTION OF PREFERRED EMBODIMENTS

First, aspects of embodiments of the present disclosure will be listed and illustrated. It is also possible to combine at least some of the embodiments described below as appropriate.

A circuit board structure according to an aspect of the present disclosure includes a circuit board portion having a mounting face on which semiconductor elements are mounted, an opposing plate portion that is opposed to the mounting face and that dissipates heat from the circuit board portion, a plurality of semiconductor elements mounted on the mounting face in a row, and a recessed portion formed at a position corresponding to the plurality of semiconductor elements in the opposing plate portion.

According to this aspect, the plurality of semiconductor elements are mounted in a row, and the recessed portion has a shape that conforms to the row of semiconductor elements. Accordingly, the structure of the circuit board portion is simplified, and, for example, if the recessed portion is formed by casting, the flowability can be improved.

In the circuit board structure according to an aspect of the present disclosure, a configuration is also possible in which, the semiconductor elements each include a first terminal on one side, and a second terminal on another side that is opposed to the one side, a current larger than the current flowing through the second terminal flows through the first terminal, and the circuit board structure further includes: a first conductive plate that is connected with the first terminal of the plurality of semiconductor elements, and a second conductive plate that is connected with the second terminal of the plurality of semiconductor elements and that is smaller than the first conductive plate.

According to this aspect, a current larger than the current flowing through the second terminal flows through the first terminal, and the second conductive plate connected to the second terminal is smaller than the first conductive plate connected to the first terminal. Accordingly, it is possible to enlarge the size of the first conductive plate through which a current larger than that flowing through the second conductive plate flows, and enhance heat dissipation performance.

The circuit board structure according to an aspect of the present disclosure may also include a heat dissipation fin that is arranged to be opposed to a wall portion of the recessed portion.

According to this aspect, the wall portion of the recessed portion is opposed to the heat dissipation fin, and thus it is possible to prevent the flow of air along the heat dissipation fin from being blocked by the wall portion of the recessed portion in advance.

In the circuit board structure according to an aspect of the present disclosure, the heat dissipation fin may also extend along a longitudinal direction of the recessed portion.

According to this aspect, the heat dissipation fin is arranged so as to be opposed to the wall portion extending in the longitudinal direction of the recessed portion, and thus it is possible to suppress the flow of air along the heat dissipation fin from being blocked by the wall portion of the recessed portion as much as possible.

The circuit board structure according to an aspect of the present disclosure may also include a heat conductive member interposed between the semiconductor elements and the recessed portion.

According to this aspect, the heat conductive member is interposed between the semiconductor elements and the recessed portion, and if heat is generated by the semiconductor elements, the heat conductive material quickly conducts the heat to the recessed portion, and the heat is dissipated to the outside via the heat dissipation fin.

The present disclosure will be described in detail with reference to the drawings illustrating the embodiments. Hereinafter, a circuit board structure according to the embodiments of the present disclosure will be described with reference to the drawings. Note, that the present disclosure is defined by the claims without being limited to these examples, and all modifications in the meaning and scope that are equivalent to the claims are intended to be encompassed herein.

Hereinafter, an electric apparatus provided with a circuit board structure according to the present embodiment will be illustrated.

### First Embodiment

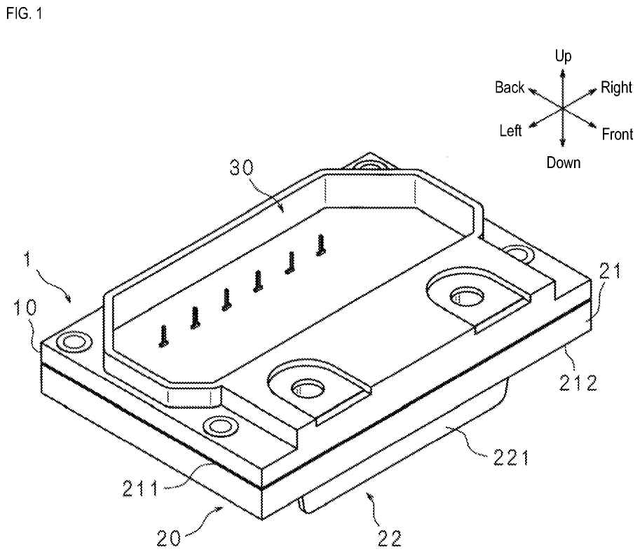

FIG. 1 is a perspective view of an electric apparatus 1 according to a first embodiment. The electric apparatus 1 is provided with a circuit board housing portion 10 and a support member 20 that supports the circuit board housing portion 10.

The electric apparatus 1 (circuit board structure) is arranged in a power supply path between a power source such as a battery mounted in a vehicle and loads constituted by in-vehicle electric components such as a lamp and a wiper, or a motor and the like. The electric apparatus 1 is used in an electric component such as a DC-DC converter or an inverter.

In the present embodiment, for illustrative reasons, “front”, “back”, “left”, “right”, “up”, and “down” of the electric apparatus 1 are defined according to the front-rear, left-right, and up-down directions shown in FIG. 1. Hereinafter, the structure of the electric apparatus 1 will be illustrated using the front, rear, left, right, up and down directions as defined above.

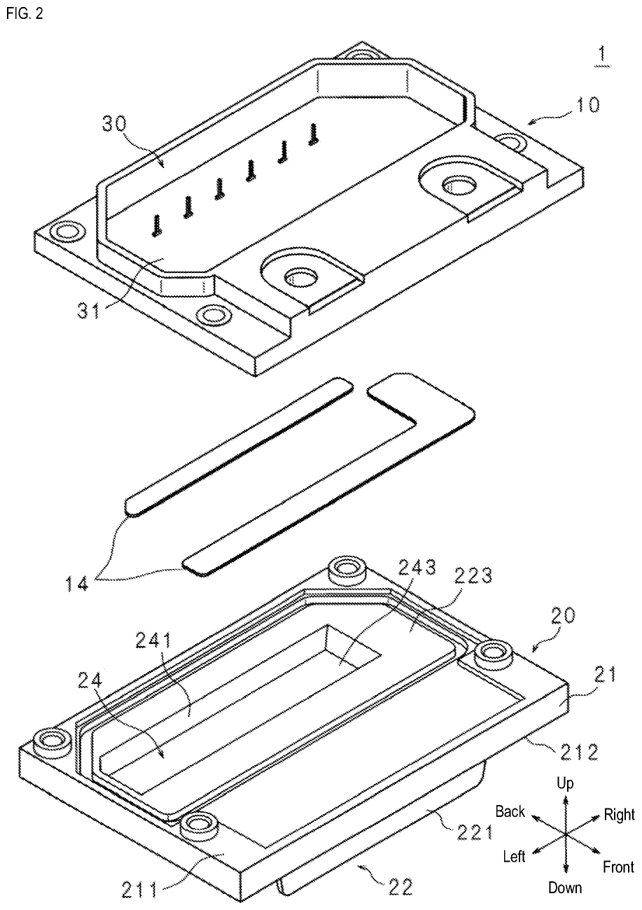

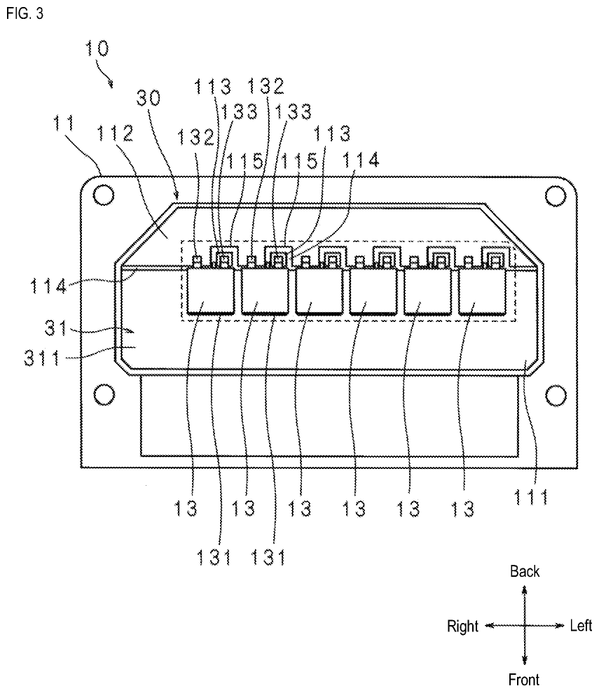

FIG. 2 is an exploded view of the electric apparatus 1 according to the present embodiment, and FIG. 3 is a schematic bottom view of the circuit board housing portion 10 of the electric apparatus 1 according to the present embodiment. In other words, FIG. 3 shows the circuit board housing portion 10 viewed from below.

The circuit board housing portion 10 includes a circuit board portion 31 constituting a power circuit, and electric components that are mounted on the circuit board portion 31. The electric components are mounted as appropriate in accordance with the usage of the electric apparatus 1, and may include a switching element such as a FET (Field Effect Transistor), a resistor, a coil, a capacitor, and the like.

The support member 20 includes a base portion 21 that supports the circuit board housing portion 10 at a circumferential edge portion 211 on the upper side, and a heat dissipation portion 22 provided on a lower face 212 that is on the opposite side of the circumferential edge portion 211. The base portion 21 and the heat dissipation portion 22 included in the support member 20 may also be formed in one piece by die-casting using a metal material such as aluminium or an aluminium alloy, for example.

The circuit board housing portion 10 includes a power circuit 30. The power circuit 30 is provided with at least a circuit board portion 31 including bus bars 111 to 113, and semiconductor switching elements 13 (semiconductor elements) mounted on the mounting face 311 on the lower side of the circuit board portion 31.

The semiconductor switching elements 13 are, for example, FETs (specifically, surface-mounting type power MOSFETs), and are mounted on the lower face of the bus bars 111 to 113. An electric component such as a Zener diode may also be mounted on the lower face of the bus bars 111 to 113 in addition to the semiconductor switching elements 13 (hereinafter referred to as FETs 13).

The FETs 13 each include, for example, a drain terminal 131 (first terminal) on the lower face (face that is opposed to the mounting face 311) of the element body, and the drain terminal 131 protrudes outward on one side of the element body. The FETs 13 also each include a source terminal 132 (second terminal) and a gate terminal 133 on another side that is opposed to the aforementioned one side.

The drain terminals 131 of the FETs 13 are connected to the bus bar 111 by soldering. The bus bar 111 will be hereinafter referred to as a drain bus bar 111 (first conductive plate). The source terminals 132 of the FETs 13 are connected to the bus bar 112 by soldering. Hereinafter, the bus bar 112 will be referred to as a source bus bar 112 (second conductive plate). The drain bus bar 111 and the source bus bar 112 are conductive plate members formed of a metal material such as copper, a copper alloy, or the like.

On the other hand, the gate terminals 133 of the FETs 13 are connected by soldering to the bus bars 113. Hereinafter, the bus bars 113 will be referred to as gate bus bars 113. The gate bus bars 113 are conductive members formed of a metal material such as copper, a copper alloy, or the like.

A resin portion 114 made of an insulative resin material is interposed between the drain bus bar 111, the source bus bar 112, and the gate bus bars 113. The drain bus bar 111, the source bus bar 112, and the gate bus bars 113 are made in one piece with the resin portion 114 to form the circuit board portion 31.

The drain bus bar 111 is larger than the source bus bar 112 and the gate bus bars 113, and is shaped like a rectangular plate. That is, the drain bus bar 111 has the largest exposed area in the circuit board portion 31, and the drain bus bar 111 occupies the most part of the front part of the circuit board portion 31. Also, the FETs 13 are fixed to the drain bus bar 111 by the drain terminals 131 thereof being soldered to one long side portion of the drain bus bar 111.

The source bus bar 112 is smaller than the drain bus bar 111, and substantially shaped like a trapezoid plate. In the circuit board portion 31, the exposed area of the source bus bar 112 is smaller than that of the drain bus bar 111. The source bus bar 112 is arranged such that the long bottom side thereof is opposed to the aforementioned one long side portion of the drain bus bar 111.

A resin portion 114 is interposed between the drain bus bar 111 and the source bus bar 112. In other words, the drain bus bar 111 and the source bus bar 112 are opposed to each other interposing the resin portion 114 therebetween. The resin portion 114 is made by, for example, an insert molding using an insulative resin material such as phenol resin, glass epoxy resin, or the like. The resin portion 114 engages with the drain bus bar 111, the source bus bar 112, and the gate bus bars 113 and join them with each other in one piece, thereby forming the circuit board portion 31.

In the source bus bar 112, a long bottom side portion opposing the one long side portion of the drain bus bar 111 to which the FETs 13 are fixed has recessed portions and protruding portions in a comb-like manner. In other words, a plurality of recessed portions 115 are formed on the long bottom side portion of the source bus bar 112. The recessed portions 115 are formed at positions corresponding to the respective gate terminals 133 of the FETs 13. In the source bus bar 112, the respective source terminals 132 of the FETs 13 are soldered to the long bottom side portion excluding the recessed portions 115.

As described above, the FETs 13 are arranged linearly so as to reach from the drain bus bar 111 (the one long side portion) and the source bus bar 112 (the long bottom side portion).

End portions of the gate bus bars 113 are arranged inside the recessed portions 115 but spaced apart from the edge of the recessed portions 115. Also, the resin portion 114 is interposed between the edge of the recessed portions 115 and the end portions of the gate bus bars 113. In other words, the end portions of the gate bus bars 113 are surrounded by the resin portion 114, thereby the gate bus bars 113 and the source bus bar 112 being insulated from each other.

The gate terminals 133 of the FETs 13 are respectively connected to the gate bus bars 113. For example, the gate bus bars 113 are substantially bent in an L-shape (not shown).

The circuit board portion 31 is substantially formed in a rectangular shape as viewed in the up-down direction, and the FETs 13 are mounted on the mounting face 311 on the lower side thereof. In other words, the lower faces of the source bus bar 112 and the gate bus bars 113 and portions of the gate bus bars 113 are level with each other, thereby forming the mounting face 311 of the circuit board portion 31. The FETs 13 are arranged in a row on the mounting face 311 along the longitudinal direction (left-right direction) of the circuit board portion 31.

In the FETs 13, a large current flows through the drain terminal 131 and the source terminal 132, and the current flowing through the drain terminal 131 is the largest of all. Accordingly, heat generated in the drain bus bar 111 is greater than heat generated in the source bus bar 112. Accordingly, in the circuit board portion 31, the ratio of the area (exposed area) of the drain bus bar 111 needs to be set larger than that of the area (exposed area) of the source bus bar 112 in order to enhance heat dissipation performance.

However, if the FETs 13 are arranged in an L-shape instead of being arranged in a row, for example, it is difficult to adjust the ratio between the area of the drain bus bar 111 and the area of the source bus bar 112 in the circuit board portion 31.

In contrast to this, in the electric apparatus 1 according to the present embodiment, as described above, the FETs 13 are arranged in a row on the mounting face 311 along the longitudinal direction (left-right direction) of the circuit board portion 31, reaching from the drain bus bar 111 (the one long side portion) to the source bus bar 112 (the long-bottom side portion). Accordingly, by simply changing the design so as to change the position of the row of the FETs 13 to a direction intersecting the row (in the original position), the ratio between the area (exposed areas) of the drain bus bar 111 and the area of the source bus bar 112 in the circuit board portion 31 can be readily adjusted.

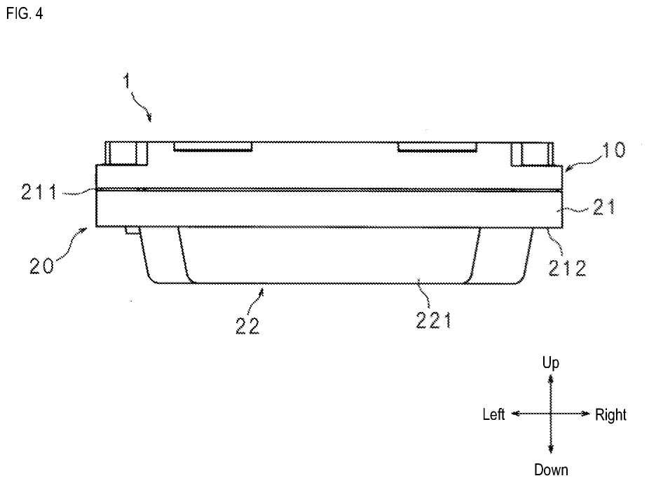

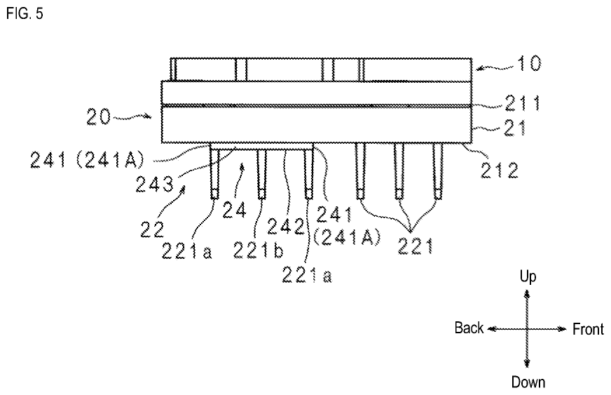

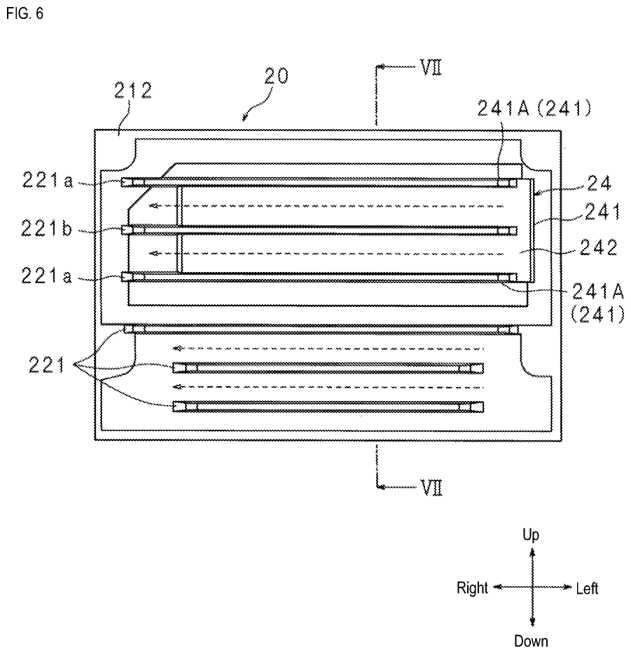

FIG. 4 is a schematic front view of the electric apparatus 1 according to the present embodiment, FIG. 5 is a schematic side view of the electric apparatus 1 according to the present embodiment, and FIG. 6 is a schematic bottom view of the electric apparatus 1 according to the present embodiment.

The base portion 21 of the support member 20 is a rectangular flat plate member having an appropriate thickness. A screw hole for fixing the circuit board housing portion 10 is formed in the circumferential edge portion 211 of the base portion 21. The circuit board housing portion 10 can be fixed to the support member 20 (base portion 21) with a screw, for example.

In the base portion 21, an opposing plate portion 223 is formed at a position that is opposed to the mounting face 311 of the circuit board portion 31 in the up-down direction and that is inside the circumferential edge portion 211. The opposing plate portion 223 is formed so as to conform to the mounting face 311 of the circuit board portion 31, and the upper face opposed to the mounting face 311 is flat.

A recessed portion 24 is recessed downward inside the opposing plate portion 223. The recessed portion 24 is provided at a position vertically corresponding to the FETs 13 arranged in a row. In other words, a region in the opposing plate portion 223 that corresponds to the row of the FETs 13 that are arranged side by side is recessed to form the recessed portion 24. In this manner, the portion of lower face of the opposing plate portion 223 that corresponds to the recessed portion 24 protrudes downward.

The recessed portion 24 is substantially formed in a rectangle as viewed in the up-down direction such that the longitudinal direction of the circuit board portion 31 corresponds to the longitudinal direction of the recessed portion 24. The recessed portion 24 includes a bottom portion 243, and a wall portion 241 that is a portion excluding the bottom portion 243. The wall portion 241 is upright in the direction intersecting the opposing plate portion 223.

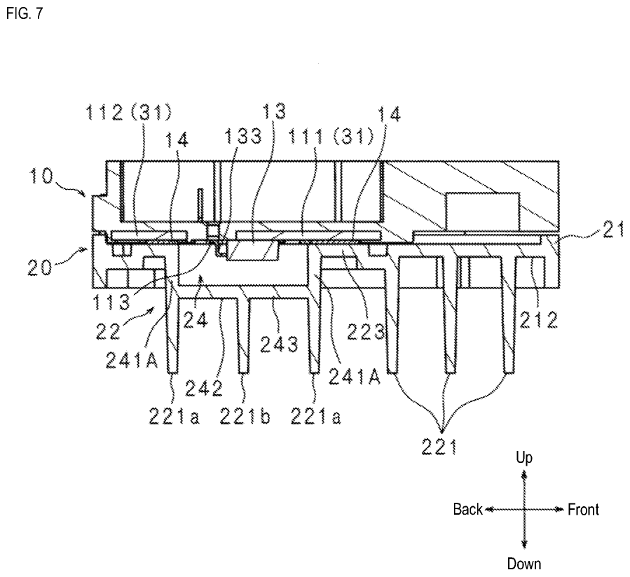

All the FETs 13 are housed inside the recessed portion 24 in the state where the circuit board housing portion 10 is fixed to the support member 20. In other words, in the state where the circuit board housing portion 10 is fixed to the support member 20, a region defined by the broken line in FIG. 3 corresponds to the recessed portion 24, and the recessed portion 24 covers all the FETs 13 (see FIG. 7).

A first heat conductive member 14 is interposed between the opposing plate portion 223 and the circuit board portion 31. The first heat conductive member 14 is, for example, a grease having high heat conductivity, a heat conductive sheet, or the like. The first heat conductive member 14 is arranged at the portion of the opposing plate portion 223 excluding the recessed portion 24, and the opposing plate portion 223 is in contact with the mounting face 311 of the circuit board portion 31 via the first heat conductive member 14. In other words, the first heat conductive member 14 is in contact with both the mounting face 311 of the circuit board portion 31 and the opposing plate portion 223. When heat is generated by the FETs 13, the heat is conducted to the circuit board portion 31 (mounting face 311), and then transferred to the opposing plate portion 223 via the first heat conductive member 14. Accordingly, heat generated by the FETs 13 can be quickly and readily transferred to the opposing plate portion 223.

A heat dissipation portion 22 is provided on the lower side of the base portion 21. The heat dissipation portion 22 is provided with a plurality of heat dissipation fins 221 protruding downward from the lower face 212 of the base portion 21, and captures heat generated in the circuit board housing portion 10 (e.g., FETs 13) and dissipates the captured heat to the outside. In other words, the heat transferred to the opposing plate portion 223 (circuit board portion 31) via the first heat conductive member 14 is cooled by air through the heat dissipation fins 221.

The heat dissipation fins 221 extend along the left-right direction, that is, the longitudinal direction of the recessed portion 24. Also, the heat dissipation fins 221 are arranged in a row spaced apart from each other in the front-rear direction. Note, that the heat dissipation fins 221 are also provided outside of the recessed portion 24.

In other words, as described above, by the recessed portion 24 being recessed downward, a protruding portion is formed on the lower face of the opposing plate portion 223. Also, in the protruding portion, the protruding end face 242 at the protruding tip, that is, the outer face of the bottom portion 243 of the recessed portion 24, is flat, and a heat dissipation fin 221a and a heat dissipation fin 221b are also provided on the protruding end face 242 as well as the other portions.

The base portion 21, the opposing plate portion 223 (recessed portion 24), and the heat dissipation fins 221 are made in one piece through die-casting using a metal material such as aluminium, an aluminium alloy, or the like.

On the other hand, in the case where the FETs 13 are arranged in a bent shape such as an L-shape, the recessed portion 24 needs to be formed in a predetermined bent shape as seen in the up-down direction that conforms to the FETs 13. However, in the case of forming such a bent shape, there is a concern that flowability of the material may be decreased at the time of casting the recessed portions 24, which may lead to an increase in the defective rate.

In contrast to this, in the electric apparatus 1 according to the present embodiment, the FETs 13 are arranged in a row, the recessed portion 24 also has a rectangular shape which conforms to the shape of the FETs 13 as seen in the up-down direction. Accordingly, the above-described problem regarding a decrease in the flowability at the time of casting can be solved.

In the heat dissipation portion 22, air flows between the heat dissipation fins 221 along the heat dissipation fins 221. On the other hand, if the wall portion 241 is provided such that the extension direction (hereinafter, longitudinal direction) of the heat dissipation fins 221 intersects the wall portion 241 of the recessed portion 24, the wall portion 241 blocks air flowing along the longitudinal direction of the heat dissipation fins 221 along the heat dissipation fins 221, and thus the flow of air in the heat dissipation portion 22 is worsened, which deteriorates heat dissipation performance of the heat dissipation portion 22.

On the other hand, if the FETs 13 are arranged in a bent shape such as an L-shape, the recessed portion 24 has a predetermined bent shape as viewed in the up-down direction, and thus there will be more cases where the wall portion 241 of the recessed portion 24 intersects the longitudinal direction of the heat dissipation fins 221.

In contrast to this, in the electric apparatus 1 according to the present embodiment, the FETs 13 are arranged in a row, the recessed portion 24 also has a rectangular shape corresponding to the shape of the FETs 13, as seen in the up-down direction, and thus the longitudinal direction of the recessed portion 24 matches the longitudinal direction of the heat dissipation fins 221. In other words, in the electric apparatus 1 according to the present embodiment, of the wall portion 241, the heat dissipation fins 221 are arranged such that the long wall portions 241A extending in the longitudinal direction of the recessed portion 24 and the longitudinal direction of the plurality of the heat dissipation fins 221 match, and thus the wall portion 241 of the recessed portion 24 is prevented from intersecting the longitudinal direction of the heat dissipation fins 221. Accordingly, the long wall portions 241A of the recessed portion 24 and the heat dissipation fins 221 are opposed to each other, and air flows between the long wall portions 241A and the heat dissipation fin 221. Accordingly, the flow of air the current flowing along the heat dissipation fins 221 is not interrupted by the wall portion 241, and thus a decrease in heat dissipation performance of the heat dissipation portion 22 can be prevented in advance (see the broken line in FIG. 6).

FIG. 7 is a vertical cross-sectional view taken along line VII-VII in FIG. 6.

As described above, the recessed portion 24 that covers all the FETs 13 is formed in the opposing plate portion 223, and the heat dissipation fins 221a and the heat dissipation fins 221b are provided along the longitudinal direction of the recessed portion 24 on the protruding end face 242 on the bottom portion 243 side of the recessed portion 24. Furthermore, the opposing plate portion 223 excluding the recessed portion 24 is in contact with the mounting face 311 of the circuit board portion 31 via the first heat conductive member 14.

As described above, when heat is generated by the FETs 13, the heat is conducted to the circuit board portion 31, and then transferred to the opposing plate portion 223 via the first heat conductive member 14. Part of the heat transferred from the FETs 13 to the opposing plate portion 223 is cooled by air through the heat dissipation fins 221. Furthermore, the remaining part of the heat transferred to the opposing plate portion 223 is transferred to the heat dissipation fins 221a and 221b via the wall portion 241 and the bottom portion 243 of the recessed portion 24, and cooled by air through the heat dissipation fins 221a and 221b.

Furthermore, in the electric apparatus 1 according to the present embodiment, the heat dissipation fins 221a formed in one piece with the long wall portions 241A are provided on the protruding end face 242 on the outer side of the recessed portion 24. More specifically, the heat dissipation fins 221a are continuous with the lower end portion of the long wall portions 241A in the direction intersecting the opposing plate portion 223. In this case, one face of the heat dissipation fin 221a is level with the outer faces of the long wall portions 241A.

In FIG. 7, for example, of the two heat dissipation fins 221a, the heat dissipation fin 221a on the right side in the drawing is level with the outer face of the long wall portion 241A on the right side in the drawing, of the two long wall portions 241A, and the heat dissipation fin 221a on the left side in the drawing is level with the outer face of the long wall portion 241A on the left side in the drawing.

With this configuration, in the electric apparatus 1 according to the present embodiment, the heat obtained by the long wall portions 241A from the circuit board portion 31 can be quickly transferred to the heat dissipation fins 221a.

In other words, in the electric apparatus 1 according to the present embodiment, the long wall portions 241A and the heat dissipation fins 221a are linearly and continuously arranged in the direction intersecting the opposing plate portion 223, and the outer face of the long wall portions 241A and one face of the heat dissipation fins 221a are level with each other and formed in one piece. Accordingly, the heat conducted to the upper end portion of the long wall portions 241A is further conducted to the tip end of the heat dissipation fins 221a at the shortest distance.

### Second Embodiment

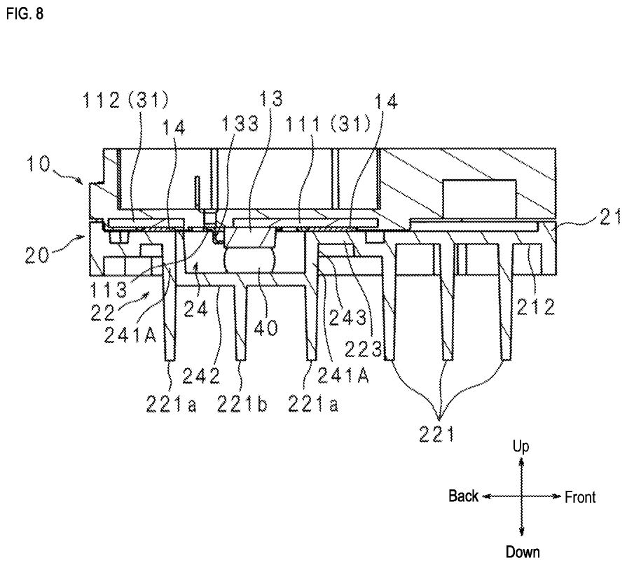

FIG. 8 is a partial vertical cross-sectional view showing a relationship between the recessed portion 24 and the FETs 13 in the electric apparatus 1 according to a second embodiment.

Similarly to the first embodiment, all the FETs 13 are covered with the recessed portion 24. Moreover, in the present embodiment, a second heat conductive member 40 is interposed between the FETs 13 and the inner face of the recessed portion 24. The second heat conductive member 40 is, for example, a highly heat-conductive grease, a heat conductive sheet, or the like. The second heat conductive member 40 is, for example, in contact with the lower face of the FETs 13 and the inner face of the recessed portion 24 and transfers the heat generated by the FETs 13 to the recessed portion 24.

In this manner, in the electric apparatus 1 according to the present embodiment, when heat is generated in the FETs 13, the heat is rapidly conducted to the recessed portion 24 via the second heat conductive member 40.

Then, the heat dissipation fins 221a and 221b obtain the heat from the recessed portion 24 and cool the obtained heat by air. Accordingly, it is possible to more effectively dissipate the heat generated by the FETs 13.

The parts same as those of the first embodiment are given the same reference numerals and the detailed description thereof is omitted.

The embodiments disclosed herein are to be considered illustrative and non-limiting in all aspects. The scope of the present disclosure is defined not by the above descriptions but by the claims, and intended to encompass all the modifications within the meanings and scope of the equivalents of the claims.

What is claimed is:

1. A circuit board structure that comprises:
a circuit board portion having a mounting face on which semiconductor elements are mounted,
an opposing plate portion that is opposed to the mounting face and that dissipates heat from the circuit board portion,
a plurality of semiconductor elements mounted on the mounting face in a row, and
a recessed portion formed at a position corresponding to the plurality of semiconductor elements in the opposing plate portion.

2. The circuit board structure according to claim 1, wherein
the semiconductor elements each include a first terminal on one side, and a second terminal on another side that is opposed to the one side, a current larger than the current flowing through the second terminal flows through the first terminal, and the circuit board structure further includes:
a first conductive plate that is connected with the first terminal of the plurality of semiconductor elements, and
a second conductive plate that is connected with the second terminal of the plurality of semiconductor elements and that is smaller than the first conductive plate.

3. The circuit board structure according to claim 1, further comprising:
a heat dissipation fin that is arranged to be opposed to a wall portion of the recessed portion.

4. The circuit board structure according to claim 3, wherein the heat dissipation fin extends along a longitudinal direction of the recessed portion.

5. The circuit board structure according to claim 1, further comprising:
a heat conductive member interposed between the semiconductor elements and the recessed portion.

6. The circuit board structure according to claim 2, further comprising:
a heat conductive member interposed between the semiconductor elements and the recessed portion.

7. The circuit board structure according to claim 3, further comprising:
a heat conductive member interposed between the semiconductor elements and the recessed portion.

8. The circuit board structure according to claim 4, further comprising:
a heat conductive member interposed between the semiconductor elements and the recessed portion.
